(19) United States
(12) Patent Application Publication
(10) Pub. No.: US 2009/0015145 A1
(43) Pub. Date: Jan. 15, 2009

(54) ORGANIC LIGHT EMITTING DEVICE

(76) Inventors: Hongki PARK, Gumi-city (KR); Hongseok CHOI, Gumi-city (KR); Woochan KIM, Gumi-city (KR)

Correspondence Address: MORGAN LEWIS & BOCKIUS LLP, 1111 PENNSYLVANIA AVENUE NW, WASHINGTON, DC, 20004, US

(21) Appl. No.: 11/952,733

(22) Filed: Dec. 7, 2007

(30) Foreign Application Priority Data
Jul. 9, 2007 (KR) 10-2007-0068666

(51) Int. Cl. H01L 27/28

(52) U.S. Cl. 313/504

(57) ABSTRACT

An organic light emitting device is disclosed. The organic light emitting device includes a substrate, a display unit on the substrate, the display unit including a plurality of subpixels, and a plurality of monitor pixels positioned outside the display unit, the monitor pixel including a light emitting area and a metal layer positioned under the light emitting area. An area of the metal layer is greater than an area of the light emitting area of the monitor pixel. A length of a side of the metal layer is greater than a length of a side of the light emitting area of the monitor pixel by substantially 10 μm to 100 μm.

This application claims the benefit of Korean Patent Application No. 10-2007-0068666 filed on Jul. 9, 2007, which is hereby incorporated by reference.

### BACKGROUND OF THE DISCLOSURE

1. Field of the Disclosure

An exemplary embodiment relates to a display device, and more particularly, to an organic light emitting device.

2. Description of the Related Art

The importance of display devices has recently increased with the growth of multimedia. Various types of display devices such as liquid crystal displays (LCDs), plasma display panels (PDPs), field emission displays (FEDs), and organic light emitting devices have been put to practical use.

Because the organic light emitting device has a high response speed of 1 ms or less, low power consumption, a self-luminance property, and an excellent viewing angle, it has been spotlighted as a next generation display device.

The organic light emitting device is classified into a top-emission type organic light emitting device and a bottom-emission type organic light emitting device depending on a light emitting direction. The organic light emitting device is classified into a passive matrix type organic light emitting device and an active matrix type organic light emitting device depending on a driving method.

If a signal is supplied to a plurality of subpixels arranged in a matrix format in a display unit of an active matrix type organic light emitting device, a transistor, a capacitor, and an organic light emitting diode inside each subpixel are driven, thereby displaying an image.

However, because driving characteristics change due to the deterioration of elements such as a thin film transistor, a capacitor and an organic light emitting diode of the organic light emitting device, the quality of the organic light emitting device is reduced.

Accordingly, various methods capable of compensating for changes in the characteristics were proposed. For instance, there is a method in which monitor pixels are provided on a substrate outside the display unit and then the subpixels inside the display unit are monitored.

A light leakage phenomenon in which light leaks from an edge area of the monitor pixels (specifically, a transparent electrode (e.g., an anode electrode) constituting the monitor pixels) to the outside is generated.

### SUMMARY OF THE DISCLOSURE

An exemplary embodiment provides an organic light emitting device capable of improving the display quality.

In one aspect, an organic light emitting device comprises a substrate, a display unit on the substrate, the display unit including a plurality of subpixels, and a plurality of monitor pixels positioned outside the display unit, the monitor pixel including a light emitting area and a metal layer positioned under the light emitting area, wherein an area of the metal layer is greater than an area of the light emitting area of the monitor pixel, and a length of a side of the metal layer is greater than a length of a side of the light emitting area of the monitor pixel by substantially 10 μm to 100 μm.

In another aspect, an organic light emitting device comprises a substrate, and a display unit on the substrate, the display unit including a plurality of subpixels, an outermost subpixel of the plurality of subpixels at an outermost position of the display unit including a light emitting area and a metal layer positioned under the light emitting area, wherein a length of a side of the metal layer is greater than a length of a side of the light emitting area of the outermost subpixel by substantially 10 μm to 100 μm.

### BRIEF DESCRIPTION OF THE DRAWINGS

The accompanying drawings, which are included to provide a further understanding of the invention and are incorporated on and constitute a part of this specification, illustrate embodiments of the invention and together with the description serve to explain the principles of the invention. In the drawings:

FIG. 1 is a bock diagram of an organic light emitting device according to an exemplary embodiment;

FIG. 2 is a plan view of the organic light emitting device;

FIGS. 3A and 3B are circuit diagrams of a subpixel of the organic light emitting device;

FIG. 4 is a plane view showing a structure of a subpixel of the organic light emitting device;

FIGS. 5A and 5B are cross-sectional views taken along line I-I′ of FIG. 4;

FIG. 6 is a cross-sectional view showing a structure of a monitor pixel of the organic light emitting device;

FIG. 7 is a plan view of a light emitting area of the monitor pixel and a metal layer positioned under the light emitting area in the organic light emitting device;

FIGS. 8A to 8C illustrate various implementations of a color image display method in the organic light emitting device; and

FIG. 9 is a cross-sectional view of the organic light emitting device.

### DETAILED DESCRIPTION OF EMBODIMENTS

Reference will now be made in detail embodiments of the invention examples of which are illustrated in the accompanying drawings.

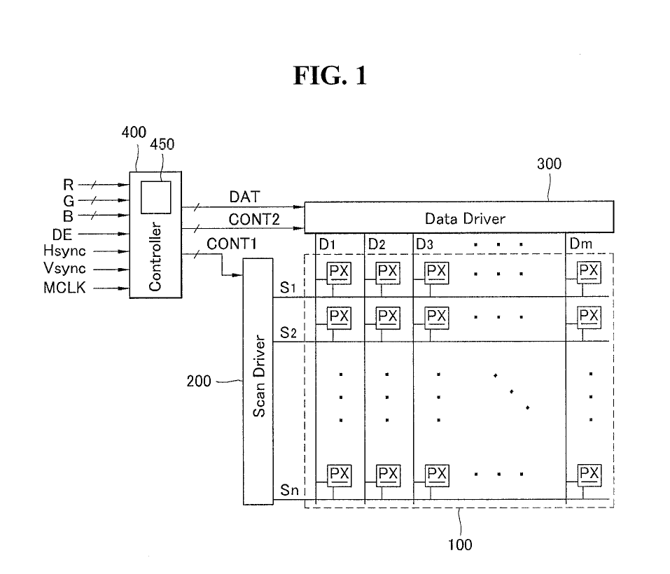

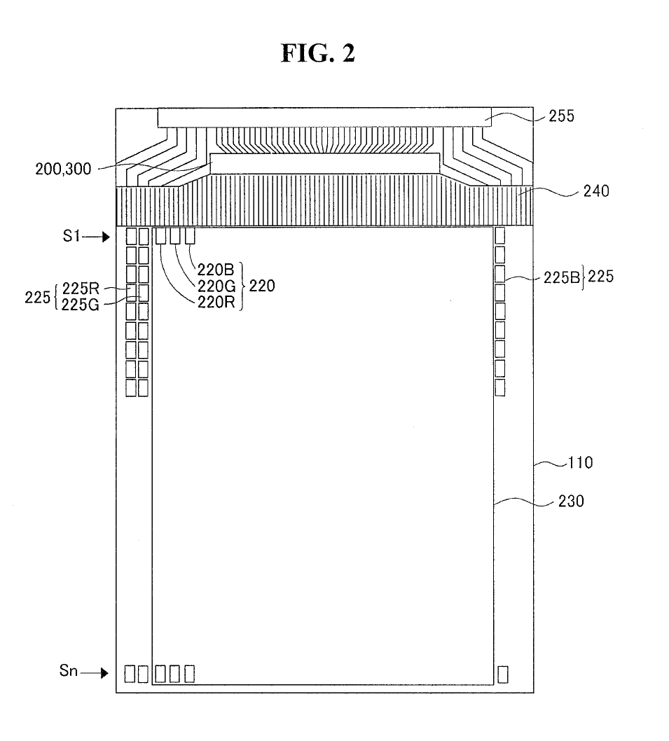

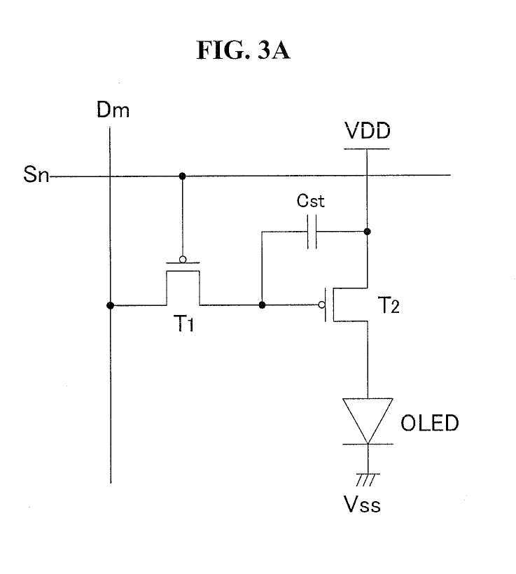

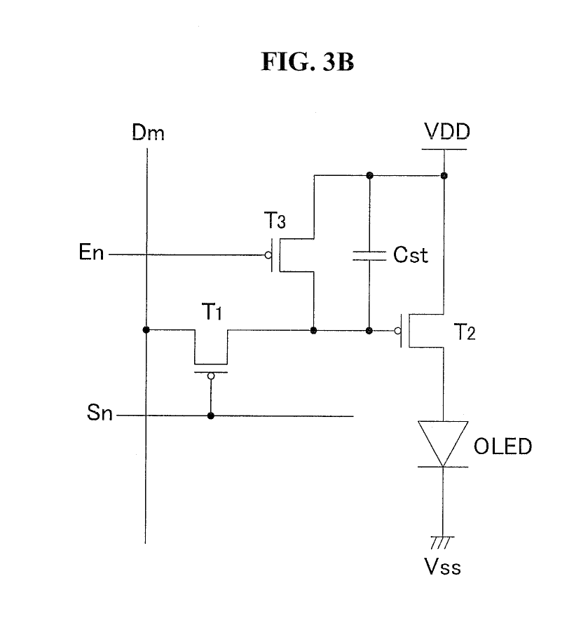

FIG. 1 is a bock diagram of an organic light emitting device according to an exemplary embodiment. FIG. 2 is a plan view of the organic light emitting device. FIGS. 3A and 3B are circuit diagrams of a subpixel of the organic light emitting device.

As shown in FIG. 1, the organic light emitting device according to the exemplary embodiment includes a display panel 100, a driver including a scan driver 200 and a data driver 300, and a controller 400.

The display panel 100 includes a plurality of signal lines S1 to Sn and D1 to Dm, a plurality of power supply lines (not shown), and a plurality of subpixels PX connected to the signal lines S1 to Sn and D1 to Dm and the power supply lines in a matrix form.

The plurality of signal lines S1 to Sn and D1 to Dm may include the plurality of scan lines S1 to Sn for sending scan signals and the plurality of data lines D1 to Dm for sending data signals. Each power supply line may send voltages such as a power voltage VDD to each subpixel PX.

Although the signal lines include the scan lines S1 to Sn and the data lines D1 to Dm in FIG. 1, the exemplary embodiment is not limited thereto. The signal lines may further include erase lines (not shown) for sending erase signals depending on a driving manner.

However, an erase line may not be used to send an erase signal. The erase signal may be sent through another signal line. For instance, although it is not shown, the erase signal may be supplied to the display panel 100 through the power supply line in case that the power supply line for supplying the power voltage VDD is formed.

As shown in FIG. 2, the organic light emitting device includes a display unit 230 in which a plurality of subpixels 220 are arranged on a substrate 110. The plurality of subpixels 220 include at least 3 color subpixels.

Below, the explanation will be given of a case where red, green, and blue subpixels 220R, 220G, and 220B are used as an example of at least 3 color subpixels. However, when the subpixels 220 include at least 4 color subpixels, the subpixels 220 may further include a white subpixel or an orange subpixel in addition to the red, green, and blue subpixels 220R, 220G, and 220B.

A non-display area, i.e., the substrate 110 positioned outside the display unit 230 includes monitor pixels 225 for monitoring the red, green, and blue subpixels 220R, 220G, and 220B.

Because the red, green, and blue subpixels 220R, 220G, and 220B are described as an example, a case where red, green, and blue monitor pixels 225R, 225G, and 225B are positioned as the monitor pixels 225 is described. The red, green, and blue monitor pixels 225R, 225G, and 225B may be disposed in each of the scan lines S1 to Sn of the display unit 230 or in only an ½ segment of the scan line.

The drivers 200 and 300 supply a data signal and a scan signal to the red, green, and blue subpixels 220R, 220G, and 220B. The drivers 200 and 300 may be divided into the data driver 300 for supplying data signals to the red, green, and blue subpixels 220R, 220G, and 220B and the scan driver 200 for supplying scan signals to the red, green, and blue subpixels 220R, 220G, and 220B.

A pad unit 255 is formed on the substrate 110 to electrically connect the substrate 110 to an external device. The pad unit 255 uses a flexible cable (for example, a flexible printed circuit (FPC)) in order to electrically connect the substrate 110 to the external device.

The external device includes, for example, a circuit board on which devices for supplying a data signal, a scan signal and power to the drivers 200 and 300 and the display unit 230 are positioned.

Signal lines 240 are divided and connected to the red, green, and blue subpixels 220R, 220G, and 220B and the red, green, and blue monitor pixels 225R, 225G, and 225B.

The signal lines 240 are connected to the drivers 200 and 300 and the pad unit 255 on the substrate 110 so as to supply a data signal, a scan signal and power to the red, green, and blue subpixels 220R, 220G and 220B and the red, green and blue monitor pixels 225R, 225G, and 225B.

As shown in FIG. 3A, the subpixel PX may include a switching thin film transistor T1 for sending the data signal in response to the scan signal sent through the scan line Sn, a capacitor Cst for storing the data signal, a driving thin film transistor T2 producing a driving current corresponding to a voltage difference between the data signal stored in the capacitor Cst and the power voltage VDD, and an organic light emitting diode (OLED) emitting light corresponding to the driving current.

As shown in FIG. 3B, the subpixel PX may include a switching thin film transistor T1 for sending the data signal in response to the scan signal sent through the scan line Sn, a capacitor Cst for storing the data signal, a driving thin film transistor T2 producing a driving current corresponding to a voltage difference between the data signal stored in the capacitor Cst and the power voltage VDD, an organic light emitting diode (OLED) emitting light corresponding to the driving current, and an erase switching thin film transistor T3 for erasing the data signal stored in the capacitor Cst in response to an erase signal sent through an erase line En.

When the organic light emitting device is driven in a digital driving manner that represents a gray scale by dividing one frame into a plurality of subfields, the pixel circuit of FIG. 3B can control an emission time by supplying an erase signal to a subfield whose a light-emission is shorter than an addressing time. The pixel circuit of FIG. 3B has an advantage capable of reducing a lowest luminance of the organic light emitting device.

A difference between driving voltages, e.g., the power voltages VDD and Vss of the organic light emitting device may change depending on the size of the display panel 100 and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| Size (S) of | | | | | | |
|---|---|---|---|---|---|---|
| display panel | VDD-Vss (R) | | VDD-Vss (G) | | VDD-Vss (B) | |
| S < 3 inches | 3.5-10 | 5 (V) | 3.5-10 | (V) | 3.5-12 | (V) |
| 3 inches < S < | 5-15 | (V) | 5-15 | (V) | 5-20 | (V) |
| 20 inches | | | | | | |
| 20 inches < S | 5-20 | (V) | 5-20 | (V) | 5-25 | (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

Referring again to FIG. 1, the scan driver 200 is connected to the scan lines S1 to Sn of the display panel 100 to apply scan signals capable of turning on the switching thin film transistor T1 to the scan lines S1 to Sn, respectively.

The data driver 300 is connected to the data lines D1 to Dm of the display panel 100 to apply data signals indicating an output video signal DAT′ to the data lines D1 to Dm, respectively.

The data driver 300 may include at least one data driving integrated circuit (IC) connected to the data lines D1 to Dm.

The data driving IC may include a shift register, a latch, a digital-to-analog (DA) converter, and an output buffer connected to one another in the order named.

When a horizontal sync start signal (STH) (or a shift clock signal) is received, the shift register can send the output video signal DAT′ to the latch in response to a data clock signal (HLCK). In case that the data driver 300 includes a plurality of data driving ICs, a shift register of a data driving IC can send a shift clock signal to a shift register of a next data driving IC.

The latch memorizes the output video signal DAT′, selects a gray voltage corresponding to the memorized output video signal DAT′ in response to a load signal, and sends the gray voltage to the output buffer.

The DA converter selects the corresponding gray voltage in response to the output video signal DAT′ and sends the gray voltage to the output buffer.

The output buffer outputs an output voltage (serving as a data signal) received from the DA converter to the data lines D1 to Dm, and maintains the output of the output voltage for 1 horizontal period (1H).

The controller 400 controls an operation of the scan driver 200 and an operation of the data driver 300. The controller 400 may include a signal conversion unit 450 that gamma-converts input video signals R, G and B into the output video signal DAT′ and produces the output video signal DAT′.

The controller 400 produces a scan control signal CONT1 and a data control signal CONT2, and the like. Then, the controller 400 outputs the scan control signal CONT1 to the scan driver 200 and outputs the data control signal CONT2 and the processed output video signal DAT′ to the data driver 300.

The controller 400 receives the input video signals R, G and B and an input control signal for controlling the display of the input video signals R, G and B from a graphic controller (not shown) outside the organic light emitting device. Examples of the input control signal include a vertical sync signal Vsync, a horizontal sync signal Hsync, a main clock signal MCLK and a data enable signal DE.

Each of the driving devices 200, 300 and 400 may be directly mounted on the display panel 100 in the form of at least one IC chip, or may be attached to the display panel 100 in the form of a tape carrier package (TCP) in a state where the driving devices 200, 300 and 400 each are mounted on a flexible printed circuit film (not shown), or may be mounted on a separate printed circuit board (not shown).

Alternatively, each of the driving devices 200, 300 and 400 may be integrated on the display panel 100 together with the plurality of signal lines S1 to Sn and D1 to Dm or the thin film transistors T1, T2 and T3, and the like.

Further, the driving devices 200, 300 and 400 may be integrated into a single chip. In this case, at least one of the driving devices 200, 300 and 400 or at least one circuit element constituting the driving devices 200, 300 and 400 may be positioned outside the single chip.

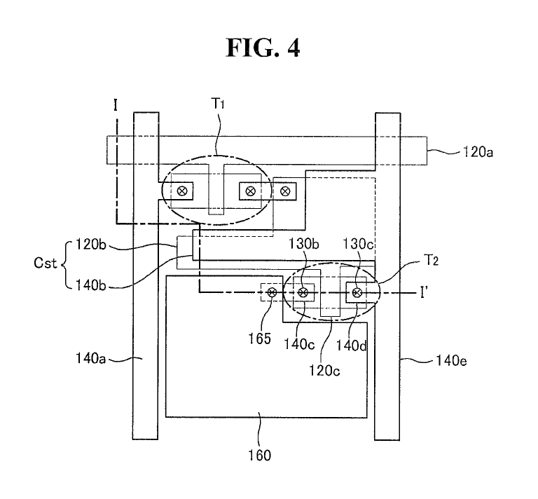

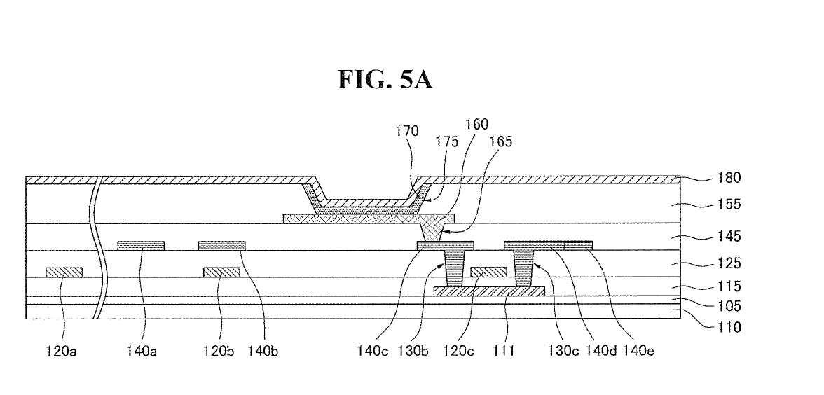

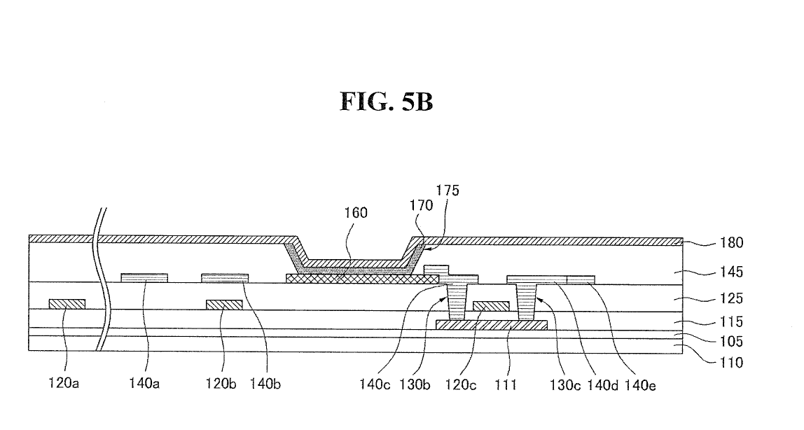

FIGS. 4, 5A and 5B show a structure of a subpixel of the organic light emitting device according to the exemplary embodiment of the present invention. This structure includes a substrate 110 having a plurality of subpixel and non-subpixel areas. As shown, for instance, in FIG. 4, the subpixel area and the non-subpixel area may be defined by a scan line 120a that extends in one direction, a data line 140a that extends substantially perpendicular to the scan line 120a, and a power supply line 140e that extends substantially parallel to the data line 140a.

The subpixel area may include a switching thin film transistor T1 connected to the scan line 120a and the data line 140a, a capacitor Cst connected to the switching thin film transistor T1 and the power supply line 140e, and a driving thin film transistor T2 connected to the capacitor Cst and the power supply line 140e. The capacitor Cst may include a capacitor lower electrode 120b and a capacitor upper electrode 140b.

The subpixel area may also include an organic light emitting diode, which includes a first electrode 160 electrically connected to the driving thin film transistor T2, an emitting layer (not shown) on the first electrode 160, and a second electrode (not shown). The non-subpixel area may include the scan line 120a, the data line 140a and the power supply line 140e.

FIGS. 5A and 5B are cross-sectional views taken along line I-I′ of FIG. 4.

As shown in FIG. 5A, a buffer layer 105 is positioned on the substrate 110. The buffer layer 105 prevents impurities (e.g., alkali ions discharged from the substrate 110) from being introduced during formation of the thin film transistor in a succeeding process. The buffer layer 105 may be selectively formed using silicon oxide (SiO₂), silicon nitride (SiNX), or using other materials. The substrate 110 may be formed of glass, plastic or metal.

A semiconductor layer 111 is positioned on the buffer layer 105. The semiconductor layer 111 may include amorphous silicon or crystallized polycrystalline silicon. The semiconductor layer 111 may include a source area and a drain area including p-type or n-type impurities. The semiconductor layer 111 may include a channel area in addition to the source area and the drain area.

A first insulating layer 115, which may be a gate insulating layer, is positioned on the semiconductor layer 111. The first insulating layer 115 may include a silicon oxide (SiO_{X}) layer, a silicon nitride (SiN_{X}) layer, or a multi-layered structure or a combination thereof.

A gate electrode 120c is positioned on the first insulating layer 115 in a given area of the semiconductor layer 111, e.g., at a location corresponding to the channel area of the semiconductor layer 111 when impurities are doped. The scan line 120a and the capacitor lower electrode 120b may be positioned on the same formation layer as the gate electrode 120c.

The gate electrode 120c may be formed of any one selected from the group consisting of molybdenum (Mo), aluminum (Al), chromium (Cr), gold (Au), titanium (Ti), nickel (Ni), neodymium (Nd) and copper (Cu), or a combination thereof. The gate electrode 120c may have a multi-layered structure formed of Mo, Al, Cr, Au, Ti, Ni, Nd, or Cu, or a combination thereof. The gate electrode 120c may have a double-layered structure including Mo/Al—Nd or Mo/Al.

The scan line 120a may be formed of any one selected from the group consisting of Mo, Al, Cr, Au, Ti, Ni, Nd, or Cu, or a combination thereof. The scan line 120a may have a multi-layered structure formed of Mo, Al, Cr, Au, Ti, Ni, Nd, or Cu, or a combination thereof. The scan line 120a may have a double-layered structure including Mo/Al—Nd or Mo/Al.

A second insulating layer 125, which may be an interlayer insulating layer or a planarization layer, is positioned on the substrate 110 on which the scan line 120a, the capacitor lower electrode 120b and the gate electrode 120c are positioned. The second insulating layer 125 may include a silicon oxide (SiO_{X}) layer, a silicon nitride (SiN_{X}) layer, or a multi-layered structure or a combination thereof.

Contact holes 130b and 130c are positioned inside the second insulating layer 125 and the first insulating layer 115 to expose a portion of the semiconductor layer 111.

A drain electrode 140c and a source electrode 140d are positioned in the subpixel area to be electrically connected to the semiconductor layer 111 through the contact holes 130b and 130c passing through the second insulating layer 125 and the first insulating layer 115.

The drain electrode 140c and the source electrode 140d may have a single-layered structure or a multi-layered structure. When the drain electrode 140c and the source electrode 140d have the single-layered structure, the drain electrode 140c and the source electrode 140d may be formed of Mo, Al, Cr, Au, Ti, Ni, Nd, or Cu, or a combination thereof.

When the drain electrode 140c and the source electrode 140d have the multi-layered structure, the drain electrode 140c and the source electrode 140d may have a double-layered structure including Mo/Al—Nd or a triple-layered structure including Mo/Al/Mo or Mo/Al—Nd/Mo.

The data line 140a, the capacitor upper electrode 140b, and the power supply line 140e may be positioned on the same formation layer as the drain electrode 140c and the source electrode 140d.

The data line 140a and the power supply line 140e positioned in the non-subpixel area may have a single-layered structure or a multi-layered structure. When the data line 140a and the power supply line 140e have the single-layered structure, the data line 140a and the power supply line 140e may be formed of Mo, Al, Cr, Au, Ti, Ni, Nd, or Cu, or a combination thereof.

When the data line 140a and the power supply line 140e have the multi-layered structure, the data line 140a and the power supply line 140e may have a double-layered structure including Mo/Al—Nd or a triple-layered structure including Mo/Al/Mo or Mo/Al—Nd/Mo. The data line 140a and the power supply line 140e may have a triple-layered structure including Mo/Al—Nd/Mo.

A third insulating layer 145 is positioned on the data line 140a, the capacitor upper electrode 104b, the drain electrode 140c, the source electrode 140d, and the power supply line 140e. The third insulating layer 145 may be a planarization layer or an interlayer insulating layer for obviating the height difference of a lower structure. The third insulating layer may be formed of an organic material such as polyimide, benzocyclobutene-based resin and acrylate or an inorganic material such as spin on glass (SOG) obtained by spin-coating silicone oxide (SiO₂) in the liquid form and solidifying it. Otherwise, the third insulating layer 145 may be a passivation layer, and may include a silicon oxide (SiO_{X}) layer, a silicon nitride (SiN_{X}) layer, or a multi-layered structure including a combination thereof.

A via hole 165 is positioned inside the third insulating layer 145 to expose any one of the source and drain electrodes 140c and 140d. The first electrode 160 is positioned on the third insulating layer 145 to be electrically connected to any one of the source and drain electrodes 140c and 140d via the via hole 165.

The first electrode 160 may be an anode electrode, and may be a transparent electrode or a reflection electrode. When the organic light emitting device has a bottom emission or dual emission structure, the first electrode 160 may be a transparent electrode formed of one of indium-tin-oxide (ITO), indium-zinc-oxide (IZO) and zinc oxide (ZnO). When the organic light emitting device has a top emission structure, the first electrode 160 may be a reflection electrode. In this case, a reflection layer formed of one of Al, Ag and Ni may be positioned under a layer formed of one of ITO, IZO and ZnO, and also the reflection layer formed of one of Al, Ag and Ni may be positioned between two layers formed of one of ITO, IZO and ZnO.

A fourth insulating layer 155 including an opening 175 is positioned on the first electrode 160. The opening 175 provides electrical insulation between the neighboring first electrodes 160 and exposes a portion of the first electrode 160. An emitting layer 170 is positioned on the first electrode 160 exposed by the opening 175. The fourth insulating layer 155 may be a pixel definition layer or a bank layer.

A second electrode 180 is positioned on the emitting layer 170. The second electrode 180 may be a cathode electrode, and may be formed of Mg, Ca, Al and Ag having a low work function or a combination thereof.

When the organic light emitting device has a top emission or dual emission structure, the second electrode 180 may be thin enough to transmit light. When the organic light emitting device has a bottom emission structure, the second electrode 180 may be thick enough to reflect light.

The organic light emitting device according to the exemplary embodiment using a total of 7 masks was described as an example. The 7 masks may be used in a process for forming each of the semiconductor layer, the gate electrode (including the scan line and the capacitor lower electrode), the contact holes, the source and drain electrodes (including the data line, the power supply line and the capacitor upper electrode), the via holes, the first electrode, and the opening.

An example of how an organic light emitting device is formed using a total of 5 masks will now be given.

As shown in FIG. 5B, the buffer layer 105 is positioned on the substrate 100, and the semiconductor layer 111 is positioned on the buffer layer 105. The first insulating layer 115 is positioned on the semiconductor layer 111. The gate electrode 120c, the capacitor lower electrode 120b, and the scan line 120a are positioned on the first insulating layer 115. The second insulating layer 125 is positioned on the gate electrode 120c.

The first electrode 160 is positioned on the second insulating layer 125, and the contact holes 130b and 130c are positioned to expose the semiconductor layer 111. The first electrode 160 and the contact holes 130b and 130c may be simultaneously formed.

The source electrode 140d, the drain electrode 140c, the data line 140a, the capacitor upper electrode 140b, and the power supply line 140e are positioned on the second insulating layer 125. A portion of the drain electrode 140c may be positioned on the first electrode 160.

A pixel or subpixel definition layer or the third insulating layer 145, which may be a bank layer, is positioned on the substrate 110 on which the above-described structure is formed. The opening 175 is positioned on the third insulating layer 145 to expose the first electrode 160. The emitting layer 170 is positioned on the first electrode 160 exposed by the opening 175, and the second electrode 180 is positioned on the emitting layer 170.

The aforementioned organic light emitting device can be manufactured using a total of 5 masks. The 5 masks are used in a process for forming each of the semiconductor layer, the gate electrode (including the scan line and the capacitor lower electrode), the first electrode (including the contact holes), the source and drain electrodes (including the data line, the power supply line and the capacitor upper electrode), and the opening. Accordingly, the organic light emitting device according to the exemplary embodiment can reduce the manufacturing cost by a reduction in the number of masks and can improve the efficiency of mass production.

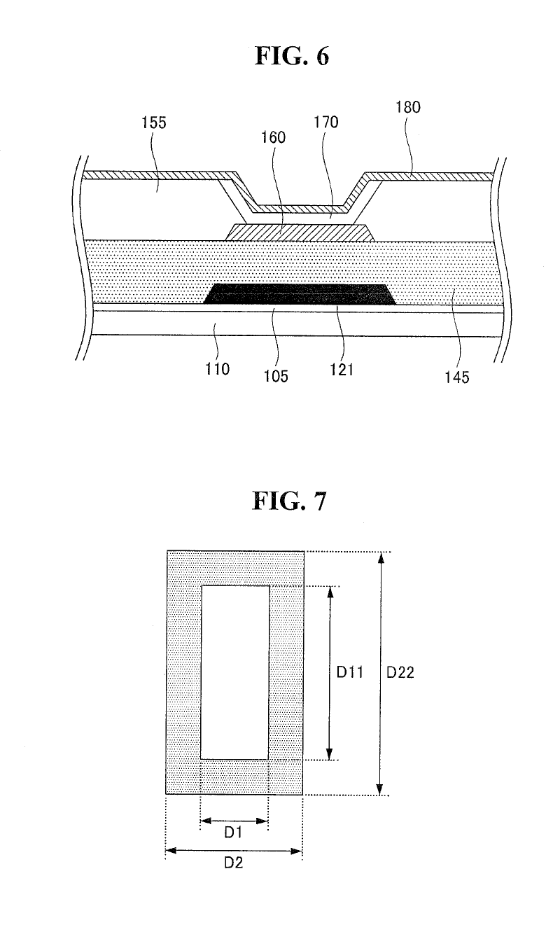

FIG. 6 is a cross-sectional view showing a structure of a monitor pixel of the organic light emitting device.

As shown in FIG. 6, the monitor pixel includes the substrate 110, the buffer layer 105, a metal layer 121, the third insulating layer 145, the first electrode 160, the fourth insulating layer 155, the emitting layer 170, and the second electrode 180.

The buffer layer 105 is positioned on the substrate 110. The buffer layer 105 may be formed using the same process as the buffer layer 105 of the subpixel.

The metal layer 121 is positioned on the buffer layer 105. The metal layer 121 may be formed using the same process as the gate electrode 120C included in a transistor of the subpixel. That is, the metal layer 121 is made of the same material as the gate electrode 120C and may perform the same function as the gate electrode 120C.

The third insulating layer 145 is positioned on the metal layer 121. The third insulating layer 145 is the same element as the third insulating layer 145 of the subpixel.

The first electrode 160 is positioned on the third insulating layer 145. The first electrode 160 may be formed using the same process as the first electrode 160 of the subpixel.

The fourth insulating layer 155 is positioned on the first electrode 160. The fourth insulating layer 155 inclines from an upper part to a lower part of the fourth insulating layer 155 to cover a part of the first electrode 160 and to expose the remaining part thereof.

An exposed portion of the first electrode 160 is defined as a light emitting area. The fourth insulating layer 155 is the same element as the fourth insulating layer 155 of the subpixel, and thus formed using the same process as the fourth insulating layer 155 of the subpixel.

The emitting layer 170 made of an organic material is positioned on the exposed portion of the first electrode 160. Therefore, as in the subpixel, the light emitting area is an area in which the emitting layer 170 can substantially emit light. A light emitting area of the monitor pixel is formed to have the same size as a light emitting area of the subpixel. The emitting layer 170 is formed using the same process as the emitting layer 170 of the subpixel.

The second electrode 180 is positioned on the emitting layer 170. The second electrode 180 is formed using the same process as the second electrode 180 of the subpixel.

Unlike the subpixel, the monitor pixel may not be operated by a transistor. However, the monitor pixel may be operated by including a transistor on a lower part of the monitor pixel, as in the subpixel.

Further, the monitor pixel acquires a voltage from power flowing to the subpixel and is interlocked with a sample hold unit in order to adjust power, specifically a current to supply to the subpixel based on the voltage. Further, the sample hold unit interlocking with the monitor pixel is interlocked with a power supply unit in order to adjust a current to supply to the subpixel.

A sample hold time may be changed according to a regular time driving method or an irregular time driving method. That is, in the drivers 200 and 300 shown in FIG. 2, a sampling time and a hold time may be changed according to a selected period among periods for supplying a data signal to the red, green, and blue subpixels 200R, 200G, and 200B.

The monitor pixel is positioned on the metal layer 121, and by forming a size of the metal layer 121 to be greater than that of a light emitting area of the monitor pixel, a light leakage phenomenon (a phenomenon in which light leaks to the outside of a panel) in the monitor pixel can be solved.

A size of the light emitting area in the monitor pixel is equal to or smaller than that of the light emitting area of the subpixel.

This is because a size of the light emitting area of the monitor pixel can be changed according to light emitting characteristics of the subpixel, i.e. light emitting characteristics of an organic material or a formation purpose of the monitor pixel.

Accordingly, an area of the metal layer 121 of the monitor pixel may be equal to or smaller than that of the gate electrode 120C positioned in a lower part of the subpixel. This is possible when an area of the subpixel is greater than that of the monitor pixel. Accordingly, it is advantageous that an area of the metal layer 121 is formed to be greater than that of the gate electrode 120C of the subpixel so as to prevent the light leakage phenomenon.

FIG. 6 has described and described a solution of the light leakage phenomenon generated in the monitor pixel by position the monitor pixel on the metal layer 121 and setting the area of the metal layer 121 to be greater than the area of the monitor pixel. There may be another solution in which an outermost subpixel is positioned on the metal layer 121 and the area of the metal layer 121 is greater than an area of a light emitting area of the outermost subpixel.

In other words, while the organic light emitting device according to the exemplary embodiment has the structure including the monitor pixels, the outermost subpixel of the plurality of subpixels may have the structure illustrated in FIG. 6 so as to prevent the light leakage phenomenon if the organic light emitting device according to the exemplary embodiment has the structure not including the monitor pixels.

FIG. 7 is a plan view of a light emitting area of the monitor pixel and a metal layer positioned under the light emitting area in the organic light emitting device. FIG. 7 shows only a light emitting area D1 and the metal layer under the monitor pixel for the convenience of explanation.

As shown in FIG. 7, an area of the metal layer may be greater than that of a light emitting area of the monitor pixel.

A length of a side of the metal layer D2 may be equal to or greater than a value in which 10 μm is added to a length of a side of the light emitting area D1 of the monitor pixel, and may be equal to or smaller than a value in which 100 μm is added to the length of a side of the light emitting area D1 of the monitor pixel.

This is represented by the following Equation 1.

(D1+5 μm×2)≦D2≦(D1+50 μm×2) [Equation 1]

A side of the light emitting area D1 and the metal layer D2 may be one of a width side and a length side.

That is, a length of a side of the light emitting area D1 and the metal layer D2 may correspond to a numerical value of a length of a length side of a light emitting area D11 and a metal layer D22 as well as a numerical value of a length of a width side of the light emitting area D1 and the metal layer D2.

Accordingly, in consideration of both a numerical value D1+5 μm×2≦D2≦D1+50 μm×2 of a width side and a numerical value D11+5 μm×2≦D22≦D11+50 μm×2 of a length side, by forming the metal layers D2 and D22 to have a size greater than the light emitting areas D1 and D11, a so-called light leakage phenomenon in which light leaks from the monitor pixel to the outside can be suppressed.

In consideration of only a numerical value of a width side, if a size of the metal layer D2 is equal to or greater than a size “D1+5 μm×2” of the light emitting area D1, because a size of the metal layer D2 is greater than that of the light emitting area D1, light is suppressed from being reflected to a side surface. If a size of the metal layer D2 is smaller than a size “D1+5 μm×2” of the light emitting area D11, light cannot be suppressed from being reflected to a side surface. This is because a minute space is formed by an insulating material covering the metal layer D2.

Even if a size of the metal layer D2 is smaller than or equal to a size “D1+50 μm×2” of the light emitting area D1, light is suppressed from being reflected to a side surface. If a size of the metal layer D2 is greater than a size “D1+50 μm×2” of the light emitting area D1, light is suppressed from being reflected to a side surface, however a bezel area, which is a non-display area increases.

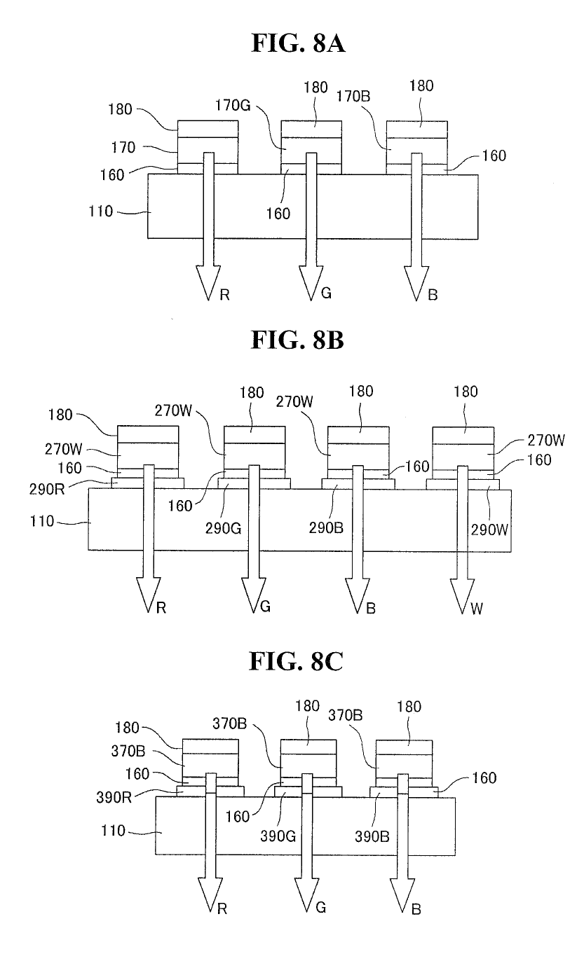

Various color image display methods may be implemented in the organic light emitting device such as described above. These methods will be described below with reference to FIGS. 8A to 8C.

FIGS. 8A to 8C illustrate various implementations of a color image display method in the organic light emitting device.

FIG. 8A illustrates a color image display method in an organic light emitting device separately including a red emitting layer 170R, a green emitting layer 170G and a blue emitting layer 170B which emit red, green and blue light, respectively.

The red, green and blue light produced by the red, green and blue emitting layers 170R, 170G and 170B is mixed to display a color image.

It may be understood in FIG. 8A that the red, green and blue emitting layers 170R, 170G and 170B each include an electron transporting layer, a hole transporting layer, and the like, on upper and lower portions thereof. It is possible to variously change the arrangement and the structure between the additional layers such as the electron transporting layer and the hole transporting layer and each of the red, green and blue emitting layers 170R, 170G and 170B.

FIG. 8B illustrates a color image display method in an organic light emitting device including a white emitting layer 270W, a red color filter 290R, a green color filter 290G, a blue color filter 290B, and a white color filter 290W.

As shown in FIG. 8B, the red color filter 290R, the green color filter 290G, the blue color filter 290B, and the white color filter 290W each transmit white light produced by the white emitting layer 270W to produce red light, green light, blue light, and white light. The red, green, blue, and white light is mixed to display a color image. The white color filter 290W may be removed depending on color sensitivity of the white light produced by the white emitting layer 270W and combination of the white light and the red, green and blue light.

While FIG. 8B has illustrated the color display method of four subpixels using combination of the red, green, blue, and white light, a color display method of three subpixels using combination of the red, green, and blue light may be used.

It may be understood in FIG. 8B that the white emitting layer 270W includes an electron transporting layer, a hole transporting layer, and the like, on upper and lower portions thereof. It is possible to variously change the arrangement and the structure between the additional layers such as the electron transporting layer and the hole transporting layer and the white emitting layer 270W.

FIG. 8C illustrates a color image display method in an organic light emitting device including a blue emitting layer 370B, a red color change medium 390R, a green color change medium 390G, a blue color change medium 390B.

As shown in FIG. 8C, the red color change medium 390R, the green color change medium 390G, and the blue color change medium 390B each transmit blue light produced by the blue emitting layer 370B to produce red light, green light and blue light. The red, green and blue light is mixed to display a color image.

The blue color change medium 390B may be removed depending on color sensitivity of the blue light produced by the blue emitting layer 370B and combination of the blue light and the red and green light.

It may be understood in FIG. 8C that the blue emitting layer 370B includes an electron transporting layer, a hole transporting layer, and the like, on upper and lower portions thereof. It is possible to variously change the arrangement and the structure between the additional layers such as the electron transporting layer and the hole transporting layer and the blue emitting layer 370B.

While FIGS. 8A and 8B have illustrated and described the organic light emitting device having a bottom emission structure, the exemplary embodiment is not limited thereto. The organic light emitting device according to the exemplary embodiment may have a top emission structure, and thus the structure of the organic light emitting device according to the exemplary embodiment may be changed depending on the top emission structure.

While FIGS. 8A to 8C have illustrated and described three kinds of color image display method, the exemplary embodiment is not limited thereto. The exemplary embodiment may use various kinds of color image display method whenever necessary.

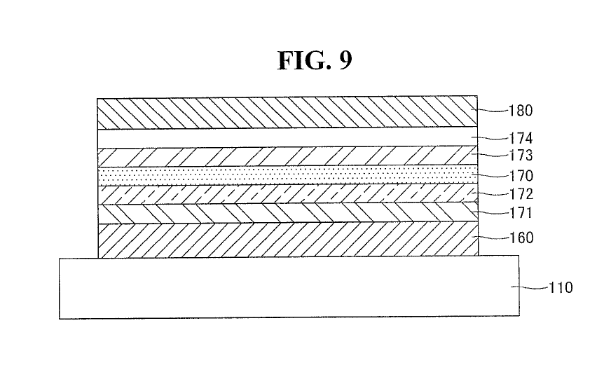

FIG. 9 is a cross-sectional view of the organic light emitting device.

As shown in FIG. 9, the organic light emitting device according to the exemplary embodiment includes the substrate 110, the first electrode 160 positioned on the substrate 110, a hole injection layer 171 positioned on the first electrode 160, a hole transporting layer 172, an emitting layer 170, an electron transporting layer 173, an electron injection layer 174, and the second electrode 180 positioned on the electron injection layer 174.

The hole injection layer 171 may function to facilitate the injection of holes from the first electrode 160 to the emitting layer 170. The hole injection layer 171 may be formed of at least one selected from the group consisting of copper phthalocyanine (CuPc), PEDOT(poly(3,4)-ethylenedioxythiophene), polyaniline (PANI) and NPD(N,N-dinaphthyl-N,N′-diphenyl benzidine), but is not limited thereto. The hole injection layer 171 may be formed using an evaporation method or a spin coating method.

The hole transporting layer 172 functions to smoothly transport holes. The hole transporting layer 172 may be formed from at least one selected from the group consisting of NPD(N,N-dinaphthyl-N,N′-diphenyl benzidine), TPD(N,N′-bis-(3-methylphenyl)-N,N′-bis-(phenyl)-benzidine, s-TAD and MTDATA(4,4′,4″-Tris(N-3-methylphenyl-N-phenyl-amino)-triphenylamine), but is not limited thereto. The hole transporting layer 172 may be formed using an evaporation method or a spin coating method.

The emitting layer 170 may be formed of a material capable of producing red, green, blue or white light, and may be formed using a phosphorescence material or a fluorescence material.

In case that the emitting layer 170 emits red light, the emitting layer 170 includes a host material including carbazole biphenyl (CBP) or N,N-dicarbazolyl-3,5-benzene (mCCP). Further, the emitting layer 170 may be formed of a phosphorescence material including a dopant material including any one selected from the group consisting of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum) or a fluorescence material including PBD:EFu(DBM)3(Phen) or Perylene, but is not limited thereto.

In case that the emitting layer 170 emits green light, the emitting layer 170 includes a host material including CBP or mCP. Further, the emitting layer 170 may be formed of a phosphorescence material including a dopant material including Ir(ppy)3(fac tris(2-phenylpyridine)iridium) or a fluorescence material including Alq3(tris(8-hydroxyquinolino)aluminum), but is not limited thereto.

In case that the emitting layer 170 emits blue light, the emitting layer 170 includes a host material including CBP or mCP. Further, the emitting layer 170 may be formed of a phosphorescence material including a dopant material including (4,6-F2 ppy)2Irpic or a fluorescence material including any one selected from the group consisting of spiro-DPVBi, spiro-6P, distyryl-benzene (DSB), distyryl-arylene (DSA), PFO-based polymers, PPV-based polymers and a combination thereof but is not limited thereto.

The electron transporting layer 173 functions to facilitate the transportation of electrons, The electron transporting layer 173 may be formed of at least one selected from the group consisting of Alq3(tris(8-hydroxyquinolino)aluminum, PBD, TAZ, spiro-PBD, BAlq, and SAlq, but is not limited thereto. The electron transporting layer 173 may be formed using an evaporation method or a spin coating method.

The electron transporting layer 173 can also function to prevent holes, which are injected from the first electrode 160 and then pass through the emitting layer 170, from moving to the second electrode 180. In other words, the electron transporting layer 173 serves as a hole stop layer, which facilitates the coupling of holes and electrons in the emitting layer 170.

The electron injection layer 174 functions to facilitate the injection of electrons. The electron injection layer 174 may be formed of Alq3(tris(8-hydroxyquinolino)aluminum), PBD, TAZ, spiro-PBD, BAlq or SAlq, but is not limited thereto. The electron injection layer 174 may be formed of an organic material and an inorganic material forming the electron injection layer 174 through a vacuum evaporation method.

The hole injection layer 171 or the electron injection layer 174 may further include an inorganic material. The inorganic material may further include a metal compound. The metal compound may include alkali metal or alkaline earth metal.

The metal compound including the alkali metal or the alkaline earth metal may include at least one selected from the group consisting of LiQ, LiF, NaF, KF, RbF, CsF, FrF, BeF₂, MgF₂, CaFe, SrF₂, BaF₂, and RbF₂, but is not limited thereto.

Thus, the inorganic material inside the electron injection layer 174 facilitates hopping of electrons injected from the second electrode 180 to the emitting layer 170, so that holes and electrons injected into the emitting layer 170 are balanced. Accordingly, emission efficiency can be improved.

Further, the inorganic material inside the hole injection layer 171 reduces the mobility of holes injected from the first electrode 160 to the emitting layer 170, so that holes and electrons injected into the emitting layer 170 are balanced. Accordingly, emission efficiency can be improved.

At least one of the electron injection layer 174, the electron transporting layer 173, the hole transporting layer 172, the hole injection layer 171 may be omitted.

As described above, the display quality of the organic light emitting device according to the exemplary embodiment can be improved by preventing the light leakage phenomenon in which light leaks from a specific area.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

What is claimed is:

1. An organic light emitting device comprising:
a substrate;
a display unit on the substrate, the display unit including a plurality of subpixels; and
a plurality of monitor pixels positioned outside the display unit, the monitor pixel including a light emitting area and a metal layer positioned under the light emitting area,
wherein an area of the metal layer is greater than an area of the light emitting area of the monitor pixel, and
a length of a side of the metal layer is greater than a length of a side of the light emitting area of the monitor pixel by substantially 10 μm to 100 μm.

2. The organic light emitting device of claim 1, wherein the subpixel or the monitor pixel includes an emitting layer, and
at least one of the emitting layer of the subpixel or the emitting layer of the monitor pixel includes a phosphorescence material.

3. The organic light emitting device of claim 1, wherein the subpixel or the monitor pixel includes an emitting layer, and
at least one of the emitting layer of the subpixel or the emitting layer of the monitor pixel includes a fluorescence material.

4. The organic light emitting device of claim 1, wherein the monitor pixel includes a first electrode, a bank layer that is positioned on the first electrode to expose a part of the first electrode, a light emitting layer positioned on the exposed part of the first electrode, and a second electrode.

5. The organic light emitting device of claim 4, wherein the light emitting area of the monitor pixel includes an area of the exposed part of the first electrode by the bank layer.

6. The organic light emitting device of claim 1, wherein the subpixel includes:
a transistor positioned on the substrate, the transistor including a gate electrode, a gate insulating layer, a semiconductor layer, a source electrode, and a drain electrode; and
an organic light emitting diode electrically connected to the transistor, the organic light emitting diode including a first electrode, an emitting layer, and a second electrode.

7. The organic light emitting device of claim 6, wherein the subpixel further includes a planarization layer on the transistor, and
the planarization layer includes a contact hole in an area corresponding to the source electrode or the drain electrode, and the first electrode is electrically connected to the source electrode or the drain electrode through the contact hole.

8. The organic light emitting device of claim 6, wherein the metal layer is formed of the substantially same material as the gate electrode.

9. The organic light emitting device of claim 1, wherein an area of the light emitting area of at least one monitor pixel is substantially equal to an area of a light emitting area of at least one subpixel.

10. The organic light emitting device of claim 1, wherein a size of the light emitting area of at least one monitor pixel is smaller than an area of a light emitting area of at least one subpixel.

11. An organic light emitting device comprising:
a substrate; and
a display unit on the substrate, the display unit including a plurality of subpixels, an outermost subpixel of the plurality of subpixels at an outermost position of the display unit including a light emitting area and a metal layer positioned under the light emitting area,
wherein a length of a side of the metal layer is greater than a length of a side of the light emitting area of the outermost subpixel by substantially 10 μm to 100 μm.

12. The organic light emitting device of claim 11, wherein the subpixels each include an emitting layer, and
at least one of the emitting layers of the subpixels includes a phosphorescence material.

13. The organic light emitting device of claim 11, wherein the subpixels each include an emitting layer, and
at least one of the emitting layers of the subpixels includes a fluorescence material.
